(19) United States
(12) Patent Application Publication
(10) Pub. No.: US 2013/0284504 A1
(43) Pub. Date: Oct. 31, 2013

(54) PRINTED CIRCUIT BOARD WITH ANTI-STATIC PROTECTION STRUCTURE

(71) Applicants: HONG FU JIN PRECISION INDUSTRY (SHENZHEN) CO, LTD., Shenzhen (CN); HON HAI PRECISION INDUSTRY CO., LTD., New Taipei (TW)

(72) Inventor: HAI-DONG TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/863,394

(22) Filed: Apr. 16, 2013

(30) Foreign Application Priority Data
Apr. 26, 2012 (CN) 201210125617.7

(51) Int. Cl. H05K 1/02; H05K 1/09

(52) U.S. Cl. CPC H05K 1/0216; H05K 1/0296; H05K 1/09
USPC 174/257; 174/262

(57) ABSTRACT

A printed circuit board includes a first conductive metal layer, a ground layer and a first insulating layer arranged between the first conductive metal layer and the ground layer. A through-hole runs through the first conductive metal layer, the first insulating layer and the ground layer. The through-hole is configured for an insertion of a ground pin of an electronic component. A second insulation layer is formed on an inside wall of the first conductive metal layer in the through-hole, thereby the ground pin inserted in the through-hole being insulated from the first conductive metal layer. A second conductive metal layer is formed on an inside wall of the ground layer and an inside wall of the first insulating layer in the through-hole, to electrically connect the ground pin to the ground layer, to provide a ground path for the electronic component.

### BACKGROUND

1. Technical Field

The present disclosure relates to printed circuit boards and, particularly, to a printed circuit board with an anti-static protection structure.

2. Description of Related Art

Most static electricity interference generated in a printed circuit board can be reduced by a ground connection. However, a poor layout of a ground layer may strengthen the electromagnetic interference.

For example, FIG. 1 shows that a printed circuit board 20 includes a conductive metal layer 21, a ground layer 22 and an insulation layer 23 arranged between the conductive metal layer 21 and the ground layer 22. A number of through-holes 24 for insertion of a number of solder feet of an electronic component 10 are defined in the printed circuit board 20, and a copper foil 25 covers the inside wall of each through-hole 24.

The electronic component 10 includes a ground pin GND connected to the ground layer 22, thus eliminating or reducing internal static electricity interference generated in the electronic component 10. However, a portion of external static electricity 30 may easily reversely flow into the electronic component 10 via the copper foil 25 and the ground pin of the electronic component 10 (shown as the direction indicated by the dotted line with an arrow), during a process that static electricity is conducted on the conductive metal layer 21, thus increasing electromagnetic interference to the electronic component 10.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic diagram of a printed circuit board of related art.

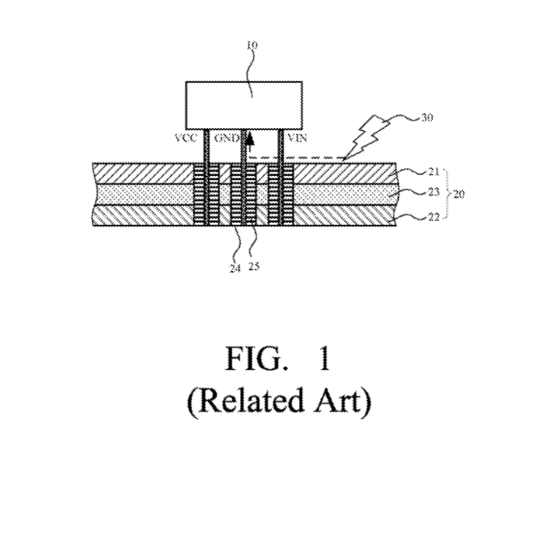

FIG. 2 is a schematic diagram of a novel printed circuit board.

### DETAILED DESCRIPTION

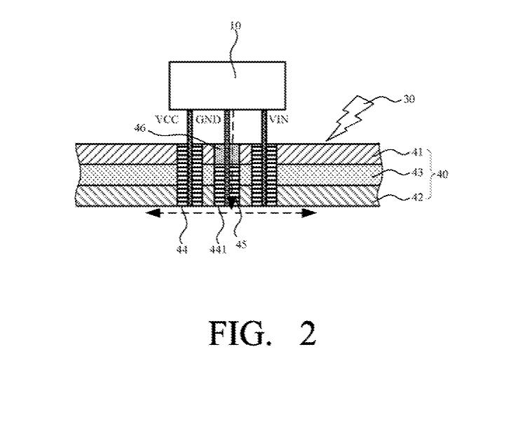

FIG. 2 shows a schematic diagram of a printed circuit board 100 with an anti-static protection structure. The printed circuit board 100 includes a first conductive metal layer 41, a ground layer 42 and a first insulating layer 43 arranged between the first conductive metal layer 41 and the ground layer 42.

A number of through-holes 44 are defined in the printed circuit board 40 running through the first conductive metal layer 41, the first insulating layer 43 and the ground layer 42. The through-holes 44 are configured for insertion of a number of solder feet of an electronic component 10. In the embodiment, the through-hole 441 is configured for an insertion of a ground pin GND of the electronic component 10. A second insulation layer 46 is formed on an inside wall of the first conductive metal layer 41 in the through-hole 441, thereby the ground pin GND inserted in the through-hole 441 being insulated from the first conductive metal layer 41. Thereby the path of external static electricity conducted to the first conductive metal layer 41 is cut off to prevent the external static electricity from flowing back into the electronic component 10 from the ground pin GND. Therefore, the amount of the static electricity interference on the electronic component 10 is effectively reduced.

A second conductive metal layer 45 is formed on an inside wall of the ground layer 42 and an inside wall of the first insulating layer 43 in the through-hole 441, to electrically connect the ground pin GND inserted in the through-hole 441 to the ground layer 42, and provide a ground path for the electronic component 10. With such a structure, a ground loop (shown as the directions indicated by the dotted lines with arrows) is formed by the ground pin GND of the electronic component 10 being connected to the ground layer 42. In the embodiment, the second conductive metal layer 45 is a copper foil.

Moreover, it is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A printed circuit board comprising:
a first conductive metal layer, a ground layer and a first insulating layer arranged between the first conductive metal layer and the ground layer; and
a through-hole running through the first conductive metal layer, the first insulating layer and the ground layer, the through-hole configured for an insertion of a ground pin of an electronic component, wherein a second insulation layer is formed on an inside wall of the first conductive metal layer in the through-hole, thereby the ground pin inserted in the through-hole being insulated from the first conductive metal layer; and a second conductive metal layer is formed on an inside wall of the ground layer and an inside wall of the first insulating layer in the through-hole, to electrically connect the ground pin inserted in the through-hole to the ground layer, to provide a ground path for the electronic component.

2. The printed circuit board according to claim 1, wherein the second conductive metal layer is a copper foil.
